(19) United States
(12) Patent Application Publication
(10) Pub. No.: US 2026/0255546 A1
(43) Pub. Date: Aug. 27, 2026

(54) HEAT DISSIPATING SHEET

(71) Applicant: TATSUTA ELECTRIC WIRE & CABLE CO., LTD., Osaka (JP)

(72) Inventors: Yuusuke HARUNA, Kyoto (JP); Hiroshi TAJIMA, Kyoto (JP)

(21) Appl. No.: 18/993,823

(22) PCT Filed: Jul. 20, 2023
(86) PCT No.: PCT/JP2023/026539

§ 371 Date: Jan. 13, 2025

(30) Foreign Application Priority Data
Jul. 22, 2022 (JP) 2022-117523

(51) Int. Cl. H05K 7/20; H05K 9/00

(52) U.S. Cl. CPC H05K 7/2039; H05K 9/0081

(57) ABSTRACT

Provided is a heat dissipating sheet being excellent in terms of an electromagnetic shielding property and heat dissipation and having flexibility. A heat dissipating sheet 1 of the present invention includes a conductive adhesive layer 2 and a heat dissipating film 3 and 4 that is formed on each of both surfaces of the conductive adhesive layer 2, in which the conductive adhesive layer 2 contains a conductive filler and a binder component and the heat dissipating film 3 or 4 contains a thermally conductive filler and a binder component. In addition, the size of an uneven shape that is formed between at least one surface of the conductive adhesive layer 2 and the heat dissipating film 3 is preferably 1 to 50 μm. In addition, as the conductive filler, a dendritic conductive filler and/or a flake-like conductive filler is preferably contained.

### TECHNICAL FIELD

The present invention relates to a heat dissipating sheet.

### BACKGROUND ART

For electronic equipment, size reduction and high-density mounting are underway, and there has been a demand for the use of a member having heat dissipation for suppressing the breakdown of electronic equipment due to heat generated from an electronic component while securing an electromagnetic shielding property, which shields electromagnetic waves that are generated from an electronic component. As a member having both an electromagnetic shielding property and heat dissipation, a heat dissipating sheet having two thermally conductive resin layers and a conductive layer that is made of a metal foil and interposed between the two resin layers as described in Patent Literature 1 is known.

### CITATION LIST

### Patent Literature

Patent Literature 1: Japanese Patent Laid-Open No. 2021-177561

### SUMMARY OF INVENTION

### Technical Problem

However, in the above-described configuration, there is a need to use a metal foil to exhibit an electromagnetic shielding property, but the metal foil itself has a hard structure, and processing, such as punching, is thus difficult. Furthermore, the use of the metal foil impairs the flexibility of the heat dissipating sheet, and the metal foil thus breaks during molding, which creates a problem of the heat dissipating sheet being not suitable for pressing.

The present invention solves such a problem, and an object of the present invention is to provide a heat dissipating sheet being excellent in terms of an electromagnetic shielding property and heat dissipation and having flexibility.

### Solution to Problem

As a result of intensive efforts to achieve the above-described object, the present inventors found that a heat dissipating sheet including a conductive adhesive layer and a heat dissipating film that is formed on each of both surfaces of the conductive adhesive layer, in which the conductive adhesive layer contains a conductive filler and a binder component and the heat dissipating film contains a thermally conductive filler and a binder component, is excellent in terms of an electromagnetic shielding property and heat dissipation and has flexibility. The present invention has been completed based on these findings.

That is, the present invention provides a heat dissipating sheet including a conductive adhesive layer and a heat dissipating film that is formed on each of both surfaces of the conductive adhesive layer, in which the conductive adhesive layer contains a conductive filler and a binder component and the heat dissipating film contains a thermally conductive filler and a binder component.

The configuration in which the conductive adhesive layer containing a conductive filler and a binder component is sandwiched between the heat dissipating films makes it possible for the conductive adhesive layer to have both heat dissipation and an electromagnetic shielding property. In addition, the conductive adhesive film has a flexible structure, which makes punching easy. Furthermore, the conductive adhesive layer and the heat dissipating film are both flexible, which makes it possible to suitably use pressing.

The size of an uneven shape that is formed between at least one surface of the conductive adhesive layer and the heat dissipating film is preferably 1 to 50 μm. The size of the uneven shape within the above-described range makes it possible to easily laminate the heat dissipating film.

As the conductive filler, a dendritic conductive filler and/or a flake-like conductive filler is preferably contained. When the conductive filler contains a dendritic conductive filler and/or a flake-like conductive filler, the isotropic conductivity of the conductive adhesive layer can be improved while the film strength of the conductive adhesive layer is improved, which makes it easy to exhibit an electromagnetic shielding property.

In addition, the heat dissipating sheet preferably has a thickness of 0.05 to 10 mm.

In addition, the heat dissipating film preferably has a thickness of 0.01 to 5 mm.

In addition, the conductive adhesive layer preferably has a thickness of 5 to 500 μm.

In addition, an adhesive strength of the heat dissipating sheet that is measured under conditions of a test speed of 50 mm/min and a test piece size of 10 mm in width is preferably 0.1 to 2 MPa.

In addition, the heat dissipating sheet preferably has hardness of 20 to 79. When the hardness is within the above-described range, sufficient flexibility is exhibited, and it becomes easy to perform punching or pressing.

### Advantageous Effects of Invention

The heat dissipating sheet of the present invention is excellent in terms of an electromagnetic shielding property and heat dissipation and has flexibility. Therefore, the heat dissipating sheet is sufficiently flexible, which makes punching possible and makes it possible to suitably use pressing.

### BRIEF DESCRIPTION OF DRAWINGS

FIG. 1 is a cross-sectional view showing one embodiment of a heat dissipating sheet of the present invention.

FIG. 2 is an enlarged view (cross-sectional view) of the vicinity of the boundary between a conducive adhesive layer 2 and a heat dissipating film 3 in a heat dissipating sheet 1 shown in FIG. 1.

### DESCRIPTION OF EMBODIMENT

### [Heat Dissipating Sheet]

A heat dissipating sheet of the present invention includes a conductive adhesive layer and a heat dissipating film that is formed on each of both surfaces of the conductive adhesive layer. The conductive adhesive layer contains a conductive filler and a binder component, and the heat dissipating film contains a thermally conductive filler and a binder component. In addition, the heat dissipating sheet may include other layers as long as the object of the present invention is not impaired.

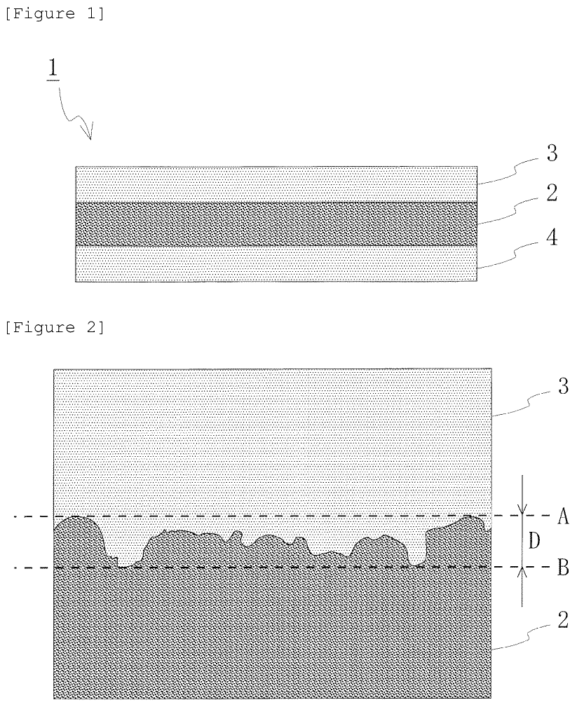

FIG. 1 shows one embodiment of the heat dissipating sheet of the present invention. A heat dissipating sheet 1 in FIG. 1 includes a conductive adhesive layer 2 and a heat dissipating film 3 and 4 laminated on each of both surfaces of the conductive adhesive layer 2. The conductive adhesive layer 2 is positioned between the heat dissipating film 3 and the heat dissipating film 4, both surfaces thereof are in contact with the heat dissipating film 3 and the heat dissipating film 4, and makes the heat dissipating film 3 and the heat dissipating film 4 adhere to each other.

The tensile strength of the heat dissipating sheet that is measured under conditions of a test speed of 50 mm/min and a test piece size of 10 mm in width is preferably 0.1 to 2 MPa, more preferably 0.15 to 1.5 MPa, and particularly preferably 0.2 to 1 MPa. When the tensile strength is 0.1 MPa or higher, the heat dissipating sheet is less likely to deform during reworking, and when the tensile strength is 2 MPa or lower, it is possible to secure flexibility.

The hardness of the heat dissipating sheet is preferably 20 to 79 and more preferably 25 to 78. When the hardness is within the above-described range, the heat dissipating sheet has sufficient flexibility, and it becomes easy to perform punching or pressing.

The thickness of the heat dissipating sheet is preferably 0.05 to 10 mm, more preferably 0.1 to 5 mm, and particularly preferably 0.2 to 3 mm. The thickness within the above-described range makes it possible to exhibit flexibility while the thickness as a heat dissipating sheet is suppressed and the heat dissipating sheet is excellent in terms of thermal conductivity and an electromagnetic shielding property.

### (Conductive Adhesive Layer)

The conductive adhesive layer contains a conductive filler and a binder component. In addition, the conductive adhesive layer may be a single layer or multiple layers composed of conductive adhesive layers that are the same or different in composition, thickness, physical properties, or the like.

Examples of the binder component include thermoplastic resins, thermosetting resins, and the like. Only one kind of the binder component may be used or two or more kinds thereof may be used.

Examples of the thermoplastic resins include polystyrene-based resins, vinyl acetate-based resins, polyester-based resins, polyolefin-based resins (for example, polyethylene-based resins, polypropylene-based resin compositions, and the like), polyimide-based resins, acrylic-based resins, and the like. Only one kind of the thermoplastic resin may be used or two or more kinds thereof may be used.

Examples of the thermosetting resins include both resins having curability (curable resins) and resins obtained by curing the curable resins. Examples of the curable resins include phenolic resins, epoxy-based resins, urethane-based resins, urethane urea-based resins, melamine-based resins, alkyd-based resins, and the like. Only one kind of the thermosetting resin may be used or two or more kinds thereof may be used. Among them, the thermosetting resin preferably contains, together with an epoxy-based resin, a thermosetting resin having a functional group capable of reacting with an epoxy group from the viewpoint of obtaining excellent reflow resistance. Such a thermosetting resin is preferably an epoxy group-modified thermosetting resin or a carboxyl group-modified thermosetting resin, and specific examples thereof include epoxy group-modified polyester resins, epoxy group-modified polyamide resins, epoxy group-modified acrylic resins, epoxy group-modified polyurethane polyurea resins, carboxyl group-modified polyester resins, carboxyl group-modified polyamide resins, carboxyl group-modified acrylic resins, carboxyl group-modified polyurethane polyurea resins, and the like. Among these, carboxyl-modified polyester resins, carboxyl-modified polyamide resins, and carboxyl-modified polyurethane polyurea resins are particularly preferable.

In a case where the thermosetting resin contains a carboxyl group-modified thermosetting resin, the acid value thereof is preferably 2 to 100 mgKOH/g, more preferably 2 to 50 mgKOH/g, and still more preferably 3 to 30 mgKOH/g. When the acid value is 2 mgKOH/g or more, the carboxyl group-modified thermosetting resin sufficiently cures together with the epoxy-based resin, which will be described below, and the heat resistance of the conductive adhesive layer thus becomes favorable. In addition, when the acid value is 100 mgKOH/g or less, the carboxyl group-modified thermosetting resin sufficiently cures together with the epoxy-based resin, which will be described below, and adhesion between the conductive adhesive layer and the heat dissipating film thus becomes favorable.

Examples of the epoxy-based resin include bisphenol-type epoxy resins such as bisphenol A-type epoxy resins, bisphenol F-type epoxy resins, bisphenol S-type epoxy resins, and hydrogenated bisphenol A-type epoxy resins; novolac-type epoxy resins such as phenol novolac-type epoxy resins and cresol novolac-type epoxy resins; aromatic epoxy resins such as biphenyl-type epoxy resins and naphthalene-type epoxy resins; nitrogen-containing ring epoxy resins such as triglycidyl isocyanurate and hydantoin epoxy resin; aliphatic epoxy resins; alicyclic epoxy resins such as dicyclocyclic epoxy resins; modified epoxy resins such as glycidyl ether-type epoxy resins, urethane modified epoxy resins, rubber modified epoxy resins, and chelate modified epoxy resin.

The epoxy equivalent of the epoxy-based resin is preferably 800 to 100000. In addition, in a case where two or more kinds of epoxy-based resins are jointly used, it is preferable to jointly use an epoxy-based resin having an epoxy equivalent of 800 to 10000 and an epoxy-based resin having an epoxy equivalent of 90 to 300. In this case, the epoxy-based resin having an epoxy equivalent of 800 to 10000 and the epoxy-based resin having an epoxy equivalent of 90 to 300 may be epoxy-based resins of the same kind or epoxy-based resins having different chemical structures.

In addition, the epoxy-based resin having an epoxy equivalent of 90 to 300 is still more preferably a novolac-type epoxy resin. The novolac-type epoxy resin has a high epoxy resin density. However, the novolac-type epoxy resin also has favorable miscibility with other epoxy resins, the difference in reactivity between epoxy groups is small, and it is thus possible to uniformly provide a high crosslinking density to an entire coated film.

The novolac-type epoxy resin is not particularly limited, and examples thereof include cresol novolac-type epoxy resins, phenol novolac-type epoxy resins, α-naphthol novolac-type epoxy resins, brominated phenol novolac-type epoxy resins, and the like.

In addition, in a case where the novolac-type epoxy resin is used as the epoxy-based resin having an epoxy equivalent of 90 to 300, it is preferable to use an epoxy resin other than novolac-type epoxy resins that are solids at normal temperature as the epoxy-based resin having an epoxy equivalent of 800 to 10000. When the binder component is composed of the novolac-type epoxy resin alone, there is a problem of insufficient adhesion, and it is thus preferable to use such a resin other than novolac-type epoxy resins as the epoxy-based resin having an epoxy equivalent of 800 to 10000. In the present invention, being solid at normal temperature means being solid under a condition of 25° C.

In the present invention, regarding the ratio between the thermosetting resin having a functional group capable of reacting with an epoxy group and the epoxy-based resin, the ratio of the epoxy-based resin is preferably 50 to 500 parts by mass, more preferably 50 to 300 parts by mass, and particularly preferably 50 to 200 parts by mass relative to 100 parts by mass of the thermosetting resin having a functional group capable of reacting with an epoxy group. When the ratio is within the above-described range, the degree of crosslinking with the thermosetting resin having a functional group capable of reacting with an epoxy group is suitably adjusted, and the flexibility and adhesion to the heat dissipating film of the conductive adhesive layer become favorable.

The content of the binder component is preferably 20 to 60 mass %, more preferably 25 to 55 mass %, and particularly preferably 30 to 50 mass % relative to the total amount of the conductive adhesive layer. When the amount of the binder component blended is within the above-described range, it becomes easy to exhibit adhesion to the heat dissipating film.

In order to exhibit an electromagnetic shielding property, examples of the conductive filler include metal powders, conductive particles such as carbon, and the like, and metal powders are preferably used from the viewpoint of exhibiting heat dissipation.

Examples of the metal powders include metal particles, metal-coated resin particles, and the like. Only one kind of the metal powder may be used or two or more kinds thereof may be used.

Examples of a metal that forms the coating portion of the metal-coated resin particles include gold, silver, copper, nickel, zinc, tine, bismuth, indium, and the like. Only one kind of the metal may be used or two or more kinds thereof may be used.

Specific examples of the metal particles include copper particles, silver particles, nickel particles, silver-coated copper particles, gold-coated copper particles, silver-coated nickel particles, gold-coated nickel particles, silver-coated alloy particles, tin-coated copper particles, tin-coated nickel particles, solder particles, and the like. Examples of the silver-coated alloy particles include silver-coated copper alloy particles obtained by coating copper-containing alloy particles (for example, copper alloy particles composed of copper, nickel, and zinc) with silver, and the like. The metal particles can be produced by an electrolysis method, an atomization method, a reduction method, or the like.

As the metal powder, among them, copper particles, silver particles, silver-coated copper particles, and silver-coated copper alloy particles are preferable. From the viewpoint of excellent conductivity and enabling suppression of the oxidation and agglomeration of the metal powder and the cost reduction of the metal powder, silver particles, silver-coated copper particles, and silver-coated copper alloy particles are preferable, and silver-coated copper particles and silver-coated copper alloy particles are particularly preferable.

The shape of the metal powder is not particularly limited, and examples thereof include a spherical shape, a flake shape (scaly shape), a dendritic shape (branch shape), a fibrous shape, an irregular shape (polyhedron), and the like. In the present invention, among them, a flake shape and a dendrite shape are preferable from the viewpoint of improving the isotropic conductivity of the conductive adhesive layer and exhibiting an electromagnetic shielding property. In addition, the average particle diameter (D50) of the metal powder is preferably 0.5 μm to 30 μm and more preferably 1 μm to 10 μm.

The content of the metal powder is preferably 40 to 90 mass %, more preferably 50 to 85 mass %, and more preferably 55 to 80 mass % relative to the total amount of the conductive adhesive layer. When the content of the metal powder is 40 mass % or more, it becomes easy to exhibit an electromagnetic shielding property, and when the content is 90 mass % or less, it becomes easy to exhibit the flexibility of the conductive adhesive layer.

In addition, the conductive adhesive layer preferably contains a curing agent. The curing agent plays a role of curing at least one curable component in the binder component. Only one kind of the curing agent may be used or two or more kinds thereof may be used.

Examples of the curing agent include isocyanate-based curing agents, phenolic curing agents, imidazole-based curing agents, amine-based curing agents, cationic curing agents, and the like. Among them, the curing agent is preferably an isocyanate-based curing agent from the viewpoint of producing an adhesive layer having excellent repairability.

Examples of the isocyanate-based curing agents include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; aromatic polyisocyanates such as 2,4-tolylene diisocyanate, 2,6-tolylene diisocyanate, 4,4′-diphenylmethane diisocyanate, and xylylene diisocyanate.

Examples of the phenolic curing agents include novolac phenol, naphthol-based compounds, and the like.

Examples of the imidazole-based curing agents include imidazole, 2-undecylimidazole, 2-heptadecylimidazole, 2-methylimidazole, 2-ethylimidazole, 2-phenyl-1-benzyl-1H-imidazole, 2-ethyl-4-methyl-imidazole, 1-cyanoethyl-2-undecylimidazole, 2-phenylimidazole, and the like.

Examples of the amine-based curing agents include aliphatic polyamines such as ethylenediamine, diethylenetriamine, triethylenetetramine, tetraethylenepentamine, dipropylenediamine, diethylaminopropylamine, and polypropylenetriamine; alicyclic polyamines such as menthenediamine, isophoronediamine, bis(4-amino-3-methyldicyclohexyl)methane, diaminodicyclohexylmethane, bis(aminomethyl)cyclohexane, N-aminoethylpiperazine, and 3,9-bis(3-aminopropyl)-3,4,8,10-tetraoxaspiro[5,5]undecane; mononuclear polyamines such as m-phenylenediamine, p-phenylenediamine, tolylene-2,4-diamine, tolylene-2,6-diamine, mesitylene-2,4-diamine, 3,5-diethyltolylene-2,4-diamine, and 3,5-diethyltolylene-2,6-diamine; aromatic polyamines such as biphenylenediamine, 4,4-diaminodiphenylmethane, 2,5-naphthylenediamine, and 2,6-naphthylenediamine; and the like.

Examples of the cationic curing agents include onium-based compounds such as amine salts of boron trifluoride, p-methoxybenzenediazonium hexafluorophosphate, diphenyliodonium hexafluorophosphate, triphenylsulfonium, tetra-n-butylphosphonium tetraphenylborate, and tetra-n-butylphosphonium-o,o-diethylphosphorodithioate; and the like.

The content of the curing agent is preferably 0.1 to 10 mass %, more preferably 0.2 to 5 mass %, and more preferably 0.3 to 3 mass % relative to the total amount of the conductive adhesive layer. When the content is within the above-described range, it is possible to make the flexibility and adhesion to the heat dissipating film of the conductive adhesive layer appropriate.

The conductive adhesive layer preferably contains a curing accelerator. Examples of the curing accelerator include imidazole-based curing accelerators. Only one kind of the curing accelerator may be used or two or more kinds thereof may be used.

Examples of the curing accelerator include compounds obtained by adding an alkyl group, an ethylcyano group, a hydroxyl group, an azine, or the like to an imidazole ring, such as 2-phenyl-4,5-dihydroxymethylimidazole, 2-heptadecylimidazole, 2,4-diamino-6-(2′-undecylimidazolyl)ethyl-S-triazine, 1-cyanoethyl-2-phenylimidazole, 2-phenylimidazole, 5-cyano-2-phenylimidazole, 2,4-diamino-6-[2′ methylimidazolyl-(1′)]-ethyl-S-triazine isocyanuric acid adduct, 2-phenylimidazole isocyanuric acid adduct, 2-methylimidazole isocyanuric acid adduct, and 1-cyanoethyl-2-phenyl-4,5-di(2-cyanoethoxy)methylimidazole; and the like.

The content of the curing accelerator is preferably 0.001 to 1.0 part by mass relative to 100 parts by mass of a resin component of the thermosetting resin having a functional group capable of reacting with an epoxy group. When the amount added is within the above-described range, it becomes easy to exhibit heat resistance, flexibility, and adhesion.

The conductive adhesive layer preferably contains urethane resin particles. The average particle diameter (D50) of the urethane resin particles is preferably 4 to 13 μm and more preferably 5 to 10 μm.

In addition, the hardness (type A durometer hardness) measured with a type A durometer in accordance with JIS K 6253 of the urethane resin particle is preferably 55 to 90. When the hardness is within the above-described range, it is possible to make the adhesion to the heat dissipating film appropriate while exhibiting reflow resistance.

The conductive adhesive layer may contain a different component other than each of the above-described components to an extent that the effect of the present invention is not impaired. Examples of the different component include components that are contained in well-known and conventional compositions. Examples thereof include an anti-foaming agent, a leveling agent, a thickener, a pressure-sensitive adhesive, a filler, a flame retardant, a colorant, and the like. Only one kind of the different component may be used or two or more kinds thereof may be used.

The content of the different component is preferably 10 mass % or less and more preferably by 5 mass % or less relative to the total amount of the conductive adhesive layer. In addition, the lower limit is 0 mass %.

The sheet resistance value measured by a four-terminal method of the conductive adhesive layer is preferably 2.0Ω/□ or less and more preferably 0.2Ω/□ or less. When the connection resistance value of the conductive adhesive layer is 2.0Ω/□ or less, the isotropic conductivity improves, and it becomes easy to exhibit an electromagnetic shielding property.

The size of an uneven shape that is formed between the conductive adhesive layer and the heat dissipating film on at least one surface is preferably 1 to 50 μm, more preferably 2 to 40 μm, and still more preferably 3 to 30 μm. A method for calculating the size of the uneven shape will be described with reference to FIG. 2. FIG. 2 is an enlarged view (cross-sectional view) of the vicinity of the boundary between the conducive adhesive layer 2 and the heat dissipating film 3 in the heat dissipating sheet 1 shown in FIG. 1. When a cross section in the thickness direction of the vicinity of the boundary between the conducive adhesive layer 2 and the heat dissipating film 3 with the conducive adhesive layer 2 on the lower side and the heat dissipating film 3 on the upper side is observed with a microscope, such as SEM as shown in FIG. 2, a distance D between a horizontal line A drawn at the highest point of the conductive adhesive layer 2 and a horizontal line B drawn at the lowest point of the conductive adhesive layer 2 can be regarded as the size of the uneven shape. More specifically, from image data (five sites) captured at a magnification of 1000 times using, for example, a scanning electron microscope (trade name “JSM-6510LA”, manufactured by JEOL Ltd.), the distances D between the horizontal line A drawn at the highest point and the horizontal line B drawn at the lowest point as described above are measured using image processing software (SEM Control User Interface Ver 3.10), and the average value of the distances measured from the images of the five sites can be regarded as the size of the uneven shape. In addition, the slope of each of the horizontal lines can be adjusted as described below. The heat dissipating sheet is often handled with a release film (PET film) laminated on the heat laminating film on the outermost surface. The boundary between the heat dissipating film and the release film is determined, and the slope of each of the horizontal lines is adjusted so that this boundary line (criterion line) between the release film and the heat dissipating film becomes parallel to the horizontal line drawn at the highest point of the conductive adhesive layer and the horizontal line drawn at the lowest point of the conductive adhesive layer, whereby the cross section of the heat dissipating film can be matched to become horizontal as described above. When the size of the uneven shape is 1 μm or more, the contact area between the conductive adhesive layer and the heat dissipating film becomes sufficient, and adhesion can be exhibited. In addition, when the size of the uneven shape is 50 μm or less, it is possible to suppress the deterioration of adhesion and heat dissipation due to bubbles that are generated between the conductive adhesive layer and the heat dissipating film.

In addition, the thickness of the conductive adhesive layer is preferably 5 to 500 μm, more preferably 10 to 400 μm, and particularly preferably 20 to 300 μm. When the thickness of the conductive adhesive layer is within the above-described range, it is possible to exhibit a shielding property while exhibiting flexibility.

### (Heat Dissipating Film)

The heat dissipating film contains a thermally conductive filler and a binder component. In addition, the heat dissipating films are formed on both surfaces of the conductive adhesive layer in a sheet shape. Among the heat dissipating films, the heat dissipating film that is formed on one surface of the conductive adhesive layer may be a single layer or multiple layers in which heat dissipating films having different compositions are laminated together. That is, the dissipating films that are formed on both surfaces of the conductive adhesive layer may be each a single layer or multiple layers, and the heat dissipating films in the heat dissipating sheet may be the same structure as or different structures from each other.

The binder component is a component that forms the matrix of the heat dissipating film. Example of the binder component include resins (binder resins) such as thermoplastic resins, thermosetting resins, and active energy-curable resins, and the like. Only one kind of the binder component may be used or two or more kinds thereof may be used.

As the thermoplastic resins, the same thermoplastic resins as those described in the above-described section of the conductive adhesive layer can be used.

Examples of the thermosetting resins include, in addition to the thermosetting resins described in the above-described section of the conductive adhesive layer, silicone-based resins from the viewpoint of thermal conductivity, heat resistance, and insulation. As the silicone-based resins, well-known and conventional silicone-based resins can be used. From the viewpoint of enabling the thermally conductive filler to be favorably dispersed without using a solvent, the silicone-based resin is preferably a two-component curable silicone resin. Only one kind of the silicone-based resin may be used or two or more kinds thereof may be used.

Examples of the active energy-curable resins include both resins that can be cured by irradiation with active energy rays (active energy-curable resins) and resins that are obtained by curing the above-described active energy-curable resin. The active energy-curable resins are not particularly limited, and it is possible to use, for example, polymers, such as polymerizable compounds having at least two (meth)acryloyloxy groups in the molecule and the like. Only one kind of the active energy-curable resin may be used or two or more kinds thereof may be used.

The content proportion of the binder component is preferably 1 to 20 mass %, more preferably 3 to 15 mass %, and particularly preferably 5 to 14 mass % relative to the total amount of the heat dissipating film. When the content proportion is 1 mass % or more, the heat dissipating film is less likely to become brittle, and the film-forming property of the heat dissipating film is excellent. Particularly, the content proportion of the silicone-based resin is preferably within the above-described range.

Examples of the thermally conductive filler include metal particles; metal oxides such as alumina (aluminum oxide), zinc oxide, and titanium oxide; nitrides such as titanium nitride, aluminum nitride, and boron nitride; metal hydroxides such as aluminum hydroxide; carbides such as silicon carbide; silicon compounds such as glass, silica, silicon carbide, and silicon (silicon); ceramic fillers; and inorganic fillers, such as carbon materials such as carbon fibers, carbon nanotubes, and diamond. Only one kind of the thermally conductive filler may be used or two or more kinds thereof may be used.

As the thermally conductive filler, among them, metal oxides and nitrides are preferable, and it is more preferable to contain both from the viewpoint of superior thermal conductivity. Particularly, as the metal oxides, titanium oxide and alumina are preferable, and as the nitrides, titanium nitride, aluminum nitride, and boron nitride are preferable. In a case where both the metal oxide and the nitride are contained, the proportion of the metal oxide is preferably 20 to 90 mass %, more preferably 30 to 70 mass %, and still more preferably 35 to 55 mass % relative to the total of the metal oxide and the nitride. When the proportion is within the above-described range, the thermal conductivity of the heat dissipating film is superior.

In a case where titanium oxide and titanium nitride are used as the metal oxide and the nitride, respectively, the median diameter of the metal oxide and the nitride are preferably 15 to 100 nm, more preferably 25 to 90 nm, and particularly preferably 40 to 85 nm. When the median diameter is 15 nm or more, the dielectric constant tends to become lower. The median diameter is the median diameter in the particle size distribution of a mixture of titanium oxide and titanium nitride.

In addition, the metal oxides other than the titanium oxide (particularly, alumina) preferably have two or more peak tops and more preferably have two peak tops in the particle size distribution. Among the two or more peak tops, one is preferably present within a range of 2 to 30 μm, and another one is preferably present within a range of 35 to 100 μm. In this case, the fillability of the metal oxides in the heat dissipating film becomes higher, and the thermal conductivity is superior.

In addition, the nitrides other than the titanium nitride (particularly, aluminum nitride) preferably have two or more peak tops and more preferably have two peak tops in the particle size distribution. Among the two or more peak tops, one is preferably present within a range of 0.5 to 20 μm, and another one is preferably present within a range of 30 to 80 μm. In this case, the fillability of the nitrides in the heat dissipating film becomes higher, and the thermal conductivity is superior.

The shape of the thermally conductive filler is not particularly limited, and examples thereof include a spherical shape (including a true sphere and an ellipsoid), a flake shape (scale shape), a dendritic shape, a lumpy shape, a flat shape, a needle shape, an irregular shape (polyhedron), and the like. Among them, a spherical shape is preferable from the viewpoint of the fillability in the heat dissipating film becoming higher, and the thermal conductivity being superior.

The thermally conductive filler may or may not have been surface-treated. As a surface treatment agent that is used for the surface treatment, a silane coupling agent is exemplified. When the thermally conductive filler is surface-treated with a silane coupling agent, the dispersibility of the thermally conductive filler into the binder component (particularly, the silicone resin), which is the matrix of the heat dissipating film, becomes favorable, and the fillability and the film-forming property are superior. Only one kind of the silane coupling agent may be used or two or more kinds thereof may be used.

Examples of the silane coupling agent include silane coupling agents having a functional group other than alkoxy groups (functional group-containing silane coupling agents), such as β-(3,4-epoxycyclohexyl)ethyltrimethoxysilane, γ-glycidoxypropyltrimethoxysilane, and γ-glycidoxypropylmethyldiethoxysilane; silane coupling agents not having functional groups other than alkoxy groups (functional group-free silane coupling agents), such as n-decyltrimethoxysilane; and the like. Among them, the functional group-free silane coupling agents are preferable, silane coupling agents in which a terminal other than alkoxy groups is an alkyl group (terminated alkyl group-containing silane coupling agents) are more preferable, and n-decyltrimethoxysilane is particularly preferable.

When the total amount of the heat dissipating film becomes 100 mass % with the thermally conductive filler and the binder component, the content proportion of the thermally conductive filler in the heat dissipating film is preferably 70 to 98 mass %, more preferably 75 to 96 mass %, still more preferably 85 to 95 mass %, and particularly preferably 90 to 94 mass % relative to 100 mass % of the total amount of the heat dissipating film. When the content proportion is 70 mass % or more, the fillability of the filler in the heat dissipating film is higher, and the thermal conductivity and the designability are superior. When the content proportion is 98 mass % or less, the heat dissipating film is less likely to become brittle, and the film-forming property at the time of producing the heat dissipating film is excellent.

The heat dissipating film may contain a different component other than each of the above-described components. Examples of the different component include a thixotropic agent, a dispersant, a curing agent, a curing accelerator, a curing retarder, a micro-tackifier, a plasticizer, a flame retardant, an antioxidant, a stabilizer, a colorant other than titanium oxide and titanium nitride, and the like.

The heat dissipating film preferably does not contain a different colorant, such as a black colorant other than titanium oxide and titanium nitride, from the viewpoint of having insulation and being excellent in terms of a low dielectric constant or the viewpoint of suppressing the curing impairing of the binder component. The heat dissipating film may contain the above-described different colorant to an extent that the effect of the present invention is not impaired. Examples of the different colorant include conductive colorants, such as carbon materials such as carbon black and carbon nanotubes. In addition, sulfur-containing colorants impair the curing of the binder component and are thus preferably not contained. The content proportion of the different colorant is preferably 30 parts by mass or less, more preferably 10 parts by mass or less, still more preferably 5 parts by mass or less, and particularly preferably 1 part by mass or less relative to 100 parts by mass of the total of titanium oxide and titanium nitride.

The thickness of the heat dissipating film is, for example, 0.01 to 5 mm and preferably 0.1 to 4 mm. When the thickness is within the above-described range, it is possible to produce the heat dissipating film with a favorable film-forming property and to sufficiently decrease the film thickness, and the heat dissipating film is thus suitably used in small electronic equipment.

The thermal conductivity in the planar direction of the heat dissipating film is preferably 4.8 W/mK or higher and more preferably 5.0 W/mK or higher. When the thermal conductivity is 4.8 W/mK or higher, the thermal conductivity and the heat dissipation are superior.

The thermal conductivity in the thickness direction of the heat dissipating film is preferably 2.5 W/mK or higher and more preferably 2.6 W/mK or higher. When the thermal conductivity is 2.5 W/mK or higher, the thermal conductivity and the heat dissipation in the thickness direction are superior.

### [Method for Producing Heat Dissipating Sheet]

The heat dissipating sheet of the preset invention can be produced by, for example, the following method. The conductive adhesive layer can be formed by, for example, applying and solidifying a conductive adhesive composition that is obtained by mixing and stirring the above-described individual components with a three-roll mill, a planetary stirring device, a planetary mixer, a homo mixer, a paddle mixer, or the like on a release film. As another aspect, the conductive adhesive layer having release films on both surfaces can also be produced by laminating another release film on the applied adhesive composition and curing the adhesive composition between the release films.

In addition, a method for producing the heat dissipating film is not particularly limited, and the heat dissipating film can be produced by a sandwich method in which a material is inserted between release films and laminated with a roll laminator or a well-known coating method with a heat press molding machine, an extruder, or the like.

The heat dissipating sheet can be produced by laminating the heat dissipating films on both surfaces of the conductive adhesive layer produced as described above.

The heat dissipating sheet produced as described above is composed of the conductive adhesive layer and the heat dissipating films, which are flexible, and can be thus easily punched, and can be pressed.

Therefore, the heat dissipating sheet of the present invention is flexible and suitable for processing while being excellent in terms of thermal conductivity and a shielding property and can be thus suitably used in small electronic components and the like.

### EXAMPLES

Hereinafter, the embodiment of the present invention will be described in more detail based on examples, but the present invention is not limited to these examples alone.

### Example 1

### <Production of Conductive Adhesive Layer>

49 Parts by mass of a mixture of a polyurethane polyurea resin having an acid value of 2 mgKOH/g and a polyurethane polyurea resin having an acid value of 26 mgKOH/g mixed in a ratio of 7:9 as a thermosetting resin having a functional group capable of reacting with an epoxy group, 18 parts by mass of a phenoxy-type epoxy resin (trade name “jER4275” manufactured by Mitsubishi Chemical Corporation), 18 parts by mass of a phenoxy novolac-type epoxy resin (trade name “jER152” manufactured by Mitsubishi Chemical Corporation), 4 parts by mass of a rubber-modified epoxy resin (trade name “ERP-4030” manufactured by Asahi Denka Co., Ltd.), 1 part by mass of trade name “DURANATE 17B-60PX” (manufactured by Asahi Kasei Chemicals Corporation) as a blocked isocyanate curing agent, 0.01 parts by mass of trade name “2MA-OK” (manufactured by Shikoku International Corporation) as an imidazole-based curing accelerator, 10 parts by mass of urethane beads (trade name “DYMIC BEADS” manufactured by Dainichiseika Color & Chemicals Mfg. Co., Ltd.) as urethane resin particles, and 150 parts by mass of a silver-coated copper powder (dendritic shape, average particle diameter (D50): 4 to 6 μm) were used, and the above-described components were blended together, thereby producing a conductive adhesive composition.

Next, the produced conductive adhesive composition was applied onto a release-treated polyethylene terephthalate film (release film) by bar coating using a doctor blade (plate-like spatula) and dried at 100° C. for three minutes, thereby producing a conductive adhesive layer having a thickness of 80 μm.

### <Production of Heat Dissipating Film>

A mixture of alumina (a mixture of 23.9 parts by mass of alumina having a median diameter of 45 μm and 17.5 parts by mass of alumina having a median diameter of 10 μm) and aluminum nitride (a mixture of 34.6 parts by mass of aluminum nitride having a median diameter of 55 μm and 23.0 parts by mass of aluminum nitride having a median diameter of 2 μm) (mass ratio=58:42) and a mixture of titanium oxide and titanium nitride (mass ratio=40:60, median diameter: 20 nm) were mixed together to produce a particle composition 1. On the alumina and the aluminum nitride, a surface treatment was performed with a silane coupling agent (trade name “Z-6210”, manufactured by Dow Corning Toray Co., Ltd., n-decyltrimethoxysilane) in advance by stirring and mixing 1 part by mass of the silane coupling agent with 100 parts by mass of the particles in a solvent. The particle composition 1 was mixed with a mixture of a first agent and a second agent of a silicone resin (trade name “TSE-3062” manufactured by Momentive Performance Materials, Inc.) to produce a resin paste. Subsequently, the resin paste was disposed between the release-treated faces of two release-treated polyethylene terephthalate films (release films) and laminated together using a roll laminator, thereby producing a laminate of “release film/resin paste layer/release film.” In addition, the laminate was heated at 70° C. for 30 minutes to thermally cure the resin paste layer, thereby producing a heat dissipating film (silicone gel sheet, thickness: 0.5 mm) as the laminate of “release film/resin paste layer/release film.”

The heat dissipating film was laminated on each of both surfaces of the conductive adhesive layer, and pressed for three minutes under conditions of a temperature of 170° C. and a pressure of 2 MPa. After that, after curing was performed at 150° C. for one hour, thereby producing a heat dissipating sheet having the heat dissipating films laminated as both outer layers on the outsides of the conductive adhesive layer as the intermediate layer.

### Example 2

A heat dissipating sheet of Example 2 was produced in the same manner as in Example 1 except that, as the heat dissipating film, an acrylic sheet containing an acrylic resin filled with a thermally conductive filler (trade name “hyper soft heat dissipating sheet 5578H” manufactured by 3M) was used instead of the silicone gel sheet.

### Comparative Example 1

Epoxy-based resin-containing non-conductive bonding films having a thickness of 25 μm (trade name “NCBF-100-D25” manufactured by TATSUTA Electric Wire and Cable Co., Ltd.) were temporarily press-bonded for five seconds to both surfaces of a copper foil having a thickness of 35 μm under conditions of a temperature of 120° C. and a pressure of 0.5 MPa, thereby producing a structure of (copper foil and adhesive layers) having the adhesive layers on both sides of the copper foil. A heat dissipating sheet of Comparative Example 1 was produced in the same manner as in Example 1 except that the (copper foil and adhesive layers) was used instead of the conductive adhesive layer.

### Comparative Example 2

A heat dissipating sheet of Comparative Example 2 was produced in the same manner as in Comparative Example 1 except that, as the heat dissipating film, the acrylic sheet of Example 2 was used.

### Evaluation

The following evaluations were performed on the heat dissipating sheets of the examples and the comparative examples produced above.

### (1) Punching Workability

A cross section of the heat dissipating sheet at the time of punching was observed with a microscope (trade name “VHX-5000” manufactured by Keyence Corporation) and evaluated as described below.

∘: The conductive adhesive layer or the copper foil does not bend or burst

×: The conductive adhesive layer or the copper foil is confirmed to bend or burst

### (2) Pressing Workability

The heat dissipating film of the produced heat dissipating sheet was peeled off, and the properties of the conductive adhesive layer or the copper foil were confirmed and evaluated as described below.
∘: No damage occurs
Δ: Wrinkles are confirmed on the conductive adhesive layer or the copper foil
×: Breakage is confirmed on the conductive adhesive layer or the copper foil

### (3) Hardness

The hardness of the produced heat dissipating sheet was measured using a rubber hardness meter (trade name “ASKER Durometer Type C” manufactured by Kobunshi Keiki Co., Ltd.) in accordance with JIS K 7312.

### Table 1

TABLE 1

| | | | Comparative | Comparative |
|---|---|---|---|---|
| | Example 1 | Example 2 | Example 1 | Example 2 |
| Both outer layers | Silicon | Acrylic | Silicon | Acrylic |
| | gel sheet | sheet | gel sheet | sheet |
| Intermediate layer | Conductive | | Copper foil and | |
| | adhesive layer | | adhesive layers | |
| Punchability | ∘ | ∘ | × | × |
| Pressability | ∘ | ∘ | Δ | × |
| Hardness | 65 | 78 | 80 | 85 |

The heat dissipating sheets of the examples having the conductive adhesive layer were flexible and were thus, consequently, excellent in terms of punchability or pressability (Examples 1 and 2). On the other hand, in the case of using a copper foil having a hard structure, the punchability or the pressability was consequently not suitable (Comparative Examples 1 and 2). In addition, the heat dissipating sheets of the examples were presumed to have both heat dissipation and an electromagnetic shielding property since the conductive adhesive layer contained the conductive filler, had isotropic conductivity, and had heat dissipation.

Hereinafter, variations of the present invention will be disclosed.

### Additional Note 1

A heat dissipating sheet including a conductive adhesive layer and a heat dissipating film that is formed on each of both surfaces of the conductive adhesive layer,
in which the conductive adhesive layer contains a conductive filler and a binder component, and
the heat dissipating film contains a thermally conductive filler and a binder component.

### Additional Note 2

The heat dissipating sheet according to Additional Note 1, in which a size of an uneven shape that is formed between at least one surface of the conductive adhesive layer and the heat dissipating film is 1 to 50 μm.

### Additional Note 3

The heat dissipating sheet according to Additional Note 1 or 2, in which, as the conductive filler, a dendritic conductive filler and/or a flake-like conductive filler is contained.

### Additional Note 4

The heat dissipating sheet according to any one of Additional Notes 1 to 3, in which the heat dissipating sheet has a thickness of 0.05 to 10 mm.

### Additional Note 5

The heat dissipating sheet according to any one of Additional Notes 1 to 4, in which at least one of the heat dissipating films has a thickness of 0.01 to 5 mm.

### Additional Note 6

The heat dissipating sheet according to any one of Additional Notes 1 to 5, in which the conductive adhesive layer has a thickness of 5 to 500 μm.

### Additional Note 7

The heat dissipating sheet according to any one of Additional Notes 1 to 6, in which a tensile strength that is measured under conditions of a test speed of 50 mm/min and a test piece size of 10 mm in width is 0.1 to 2 MPa.

### Additional Note 8

The heat dissipating sheet according to any one of Additional Notes 1 to 7, in which hardness is 20 to 79.

### REFERENCE SIGNS LIST

1 Heat dissipating sheet
2 Conductive adhesive layer
3, 4 Heat dissipating film

1. A heat dissipating sheet comprising:
a conductive adhesive layer; and
a heat dissipating film that is formed on each of both surfaces of the conductive adhesive layer,
wherein the conductive adhesive layer contains a conductive filler and a binder component, and
the heat dissipating film contains a thermally conductive filler and a binder component.

2. The heat dissipating sheet according to claim 1, wherein a size of an uneven shape that is formed between at least one surface of the conductive adhesive layer and the heat dissipating film is 1 to 50 μm.

3. The heat dissipating sheet according to claim 1, wherein, as the conductive filler, a dendritic conductive filler and/or a flake-like conductive filler is contained.

4. The heat dissipating sheet according to claim 1, wherein the heat dissipating sheet has a thickness of 0.05 to 10 mm.

5. The heat dissipating sheet according to claim 1, wherein at least one of the heat dissipating films has a thickness of 0.01 to 5 mm.

6. The heat dissipating sheet according to claim 1, wherein the conductive adhesive layer has a thickness of 5 to 500 μm.

7. The heat dissipating sheet according to claim 1, wherein a tensile strength that is measured under conditions of a test speed of 50 mm/min and a test piece size of 10 mm in width is 0.1 to 2 MPa.

8. The heat dissipating sheet according to claim 1, wherein hardness is 20 to 79.
